(19) United States
(12) Patent Application Publication
(10) Pub. No.: US 2025/0055451 A1
(43) Pub. Date: Feb. 13, 2025

(54) UNDER VOLTAGE LOCK-OUT CIRCUIT

(71) Applicant: Tagore Technology, Inc., Arlington Heights, IL (US)

(72) Inventors: Pramit SARKAR, Kolkata (IN); Manish SHAH, Vernon Hills, IL (US)

(21) Appl. No.: 18/928,390

(22) Filed: Oct. 28, 2024

Related U.S. Application Data
(63) Continuation of application No. 17/548,765, filed on Dec. 13, 2021, now Pat. No. 12,132,470.

(51) Int. Cl. H03K 17/0812; H01L 23/62; H01L 29/20

(52) U.S. Cl. CPC H03K 17/08122; H01L 23/62; H01L 29/2003

(57) ABSTRACT

A GaN based under voltage lock-out circuit includes a supply voltage input, a signal output, and a reference voltage circuit interface. Also included is a first transistor having a source and gate both coupled to the supply voltage input, and a drain coupled to a first port of the reference voltage circuit interface. Further included is a second transistor having a gate coupled to the drain of the first transistor via a second port of the reference voltage circuit interface, a drain coupled to the signal output and coupled, via a first resistor, to the supply voltage input, and a source coupled, via a second resistor, to a ground potential. Also included is a third transistor having a gate coupled to the signal output, a drain coupled through a third resistor to the source of the first transistor, and a third source coupled to the drain of the second transistor.

### BACKGROUND

### Field

This invention relates generally to active solid-state devices, and more specifically to an under voltage lock-out circuit fabricated using a gallium nitride semiconductor process.

### Related Art

A semiconductor power switch allows or blocks flow of electric current as dictated by a signal received at its control input which is typically its gate terminal. A semiconductor power switch usually needs a driver for its proper operation.

The driver receives command signals from a controller to turn on or turn off the semiconductor power switch, and then the driver communicates a signal to the semiconductor power switch while providing necessary current and voltage levels in a way which is suitable and safe. The driver also controls a rate of turn-on and turn-off as required by an application. The driver helps maintain the off condition or the on condition in face of an environmental or an application-generated disturbance. The driver may also provide other functions such as safety from over voltage or under voltage, and safety from high current, excessive rate of change of voltage, and excessive temperature.

A gallium nitride (hereinafter “GaN”) device may be used as a semiconductor power switch and provides benefits of high switching speeds and low switching losses for a given breakdown voltage and switch size. These characteristics are beneficial in a number of applications ranging from power electronics converters to audio amplifiers to LiDAR.

When used as a switching device, the benefit of a high switching speed is more fully realized only when a GaN device is made capable of operating at a high speed of operation. If a semiconductor power switch and its driver are not on the same die, then parasitic elements, such as die-to-die or die-to-package inductances and capacitances limit the speed of operation. Therefore, if a GaN semiconductor power switch and its GaN driver are made on the same die, i.e., both are fabricated in a GaN process, then potentially much better speed of operation and performance can be achieved.

At the present state of the art, commercially available GaN process produces only N-type of devices, and complementary P-types are not available. Therefore, complementary metal oxide semiconductor (hereinafter “CMOS”) type of designs, which rely heavily on complementary devices, are not possible for circuits fabricated in a GaN process. A lack of complementary devices greatly limits choice and performance of circuits in GaN technology.

A GaN transistor, often called a high-electron-mobility transistor (hereinafter “HEMT”), can be a depletion-mode device or an enhancement-mode device. Transistors of both types provide an on path from drain-to-source terminals when the gate-to-source voltage is higher than a certain threshold voltage (V_{T}). A depletion-mode device has a negative V_{T} and hence is normally-on device. That is, even when its gate-to-source voltage is 0V, the device is on. The depletion device turns off only when its gate terminal is biased at a negative voltage with respect to its source terminal by a margin larger than the threshold voltage. On the other hand, an enhancement-mode device has a positive V_{T}, and hence it is a normally-off device. That is, the device is off when its gate to source voltage is zero, and it turns on only when the gate to source voltage goes above the positive V_{T} of the device.

A depletion-mode device or an enhancement-mode device may be used as a power switch, but because a depletion-mode device is normally on, it needs a series device in a different process (for example, a silicon process) or a complicated negative gate drive voltage to turn it off. Therefore, an enhancement-mode HEMT device has a clear advantage in terms of gate drive requirement, and is usually the device of choice.

An enhancement-mode HEMT is normally on when its gate-to-source voltage is 0V. An N-channel, enhancement-mode HEMT turns off when its gate-to-source voltage is less than its threshold voltage or when its gate terminal is biased at a negative voltage with respect to its source terminal.

The behavior of GaN devices is not exactly the same as the behavior of silicon devices. In general, process variations are higher in GaN processes than in silicon processes. For example, the threshold voltage of a GaN device changes by a much larger amount due to process variations than does the threshold voltage of a CMOS device due to process variations. The threshold voltage of GaN HEMT may vary, for example, from 0.5V to 2.2V depending upon the manufacturing process. However, the threshold voltage of all GaN high-electron-mobility transistors in a die is within a reasonable range.

GaN wafers are relatively costly as compared to silicon wafers, and, as device minimum sizes are still quite large, packaging densities are low. This means that only simple circuits with a limited number of components can be packed within a die in a cost-effective manner.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a simplified block diagram of system-level architecture of an electronic system comprising a GaN driver including an under voltage lock-out circuit in accordance with the invention and a GaN power switch.

FIG. 2 is a simplified block diagram of subsystem-level architecture of a first embodiment of the under voltage lock-out circuit including an under-voltage detector in accordance with the invention, and a pulse stretcher in accordance with the invention.

FIG. 3 is a simplified schematic of an embodiment of the under-voltage detector of FIG. 2.

FIG. 4 is a simplified block diagram of subsystem-level architecture of a second embodiment of the under voltage lock-out circuit including an under-voltage detector in accordance with the invention, a pulse stretcher in accordance with the invention, and an external reference.

FIG. 5 is a simplified schematic of one embodiment of the under-voltage detector of FIG. 4.

FIG. 6 is a simplified schematic of another embodiment of the under-voltage detector of FIG. 4.

FIG. 7 is a simplified schematic of an embodiment of the pulse stretcher.

FIG. 8 is a graph of voltage versus time and shows a duration for which a UVLO signal is increased by the pulse stretcher.

### DETAILED DESCRIPTION

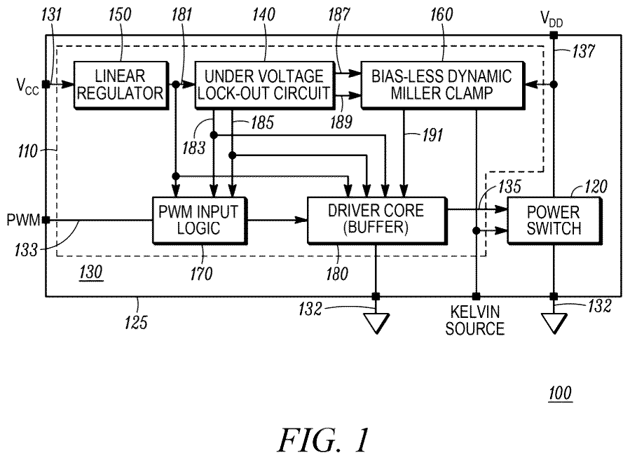

FIG. 1 is a simplified block diagram of system-level architecture of an electronic system 100 including a GaN driver 110 and a GaN field-effect transistor (hereinafter “FET”) power switch 120 in accordance with one embodiment of the invention. An integrated circuit 125 in accordance with one embodiment of the invention comprises the GaN driver 110 and the GaN FET power switch (hereinafter “GaN power switch”) 120 monolithically integrated on a single substrate, or die 130. The single die 130 may be disposed in a microelectronic package (not shown). An output terminal of the GaN driver 110 is coupled to a gate terminal of the GaN power switch 120. The GaN driver 110 is coupled to a low-voltage (less than 30V) positive supply V_{CC} 131 which may be unregulated. The GaN driver 110 is also coupled to a ground terminal 132. The GaN driver 110 typically receives a low voltage digital or pulse width modulated (PWM) signal 133 from a controller (not shown). The GaN driver 110 creates an output signal 135 having a same frequency and duty cycle as the signal from the controller but strong enough to handle capacitance of the GaN power switch 120. The GaN power switch 120 is coupled to a high-voltage (approximately 300V to 600V) positive power supply V_{DD} 137 and to the ground terminal 132.

In one embodiment, the GaN driver 110 comprises an under voltage lock-out circuit 140 in accordance with the invention, a linear regulator 150, a bias-less dynamic Miller clamp 160, a PWM input logic circuit 170, and a driver core (buffer) circuit 180, coupled as shown in FIG. 1. The under voltage lock-out circuit 140 receives a regulated supply voltage V_{SUPP} 181 from the linear regular 150. The under voltage lock-out circuit 140 outputs an under voltage lock-out (hereinafter “UVLO”) signal 183 and a stretched_UVLO signal 185 to the PWM input logic circuit 170 and to the driver core (buffer) circuit 180. The under voltage lock-out circuit 140 also outputs a stretched_UVLO_b signal 187 and a UVLO_b signal 189 to the bias-less dynamic Miller clamp 160. The bias-less dynamic Miller clamp 160 outputs a gate pulldown device signal 191 to the driver core (buffer) circuit 180.

For an integrated circuit to work properly as intended, its supply voltage needs to be within a predetermined range. If V_{SUPP} 181 of the integrated circuit 125 is not within the predetermined range, and if the GaN driver 110 nevertheless were to pass the output signal 135 to the GaN power switch 120, then the GaN power switch might turn on with a high on-state resistance. If the GaN power switch 120 were to conduct a rated amount of current, then, due to its high on-state resistance, generated heat will be greater than its design capacity, which may damage the GaN power switch. When V_{SUPP} 181 is low, some or all of the parts of the integrated circuit 125 might malfunction which can lead to serious failures.

The under voltage lock-out circuit 140 disables (or locks-out) at least some functionalities of the GaN driver 110 when V_{SUPP} 181 is below the predetermined range. When the under voltage lock-out circuit 140 disables at least some functionalities of the GaN driver 110, a gate voltage 135 of the GaN power switch 120 remains low. The low gate voltage causes the GaN power switch 120 to remain off regardless of the PWM signal 133 from the controller.

When V_{SUPP} 181 of the integrated circuit 125 is within the predetermined range, the PWM signal 133 is allowed to pass through the GaN driver 110 to control the gate of the GaN power switch 120.

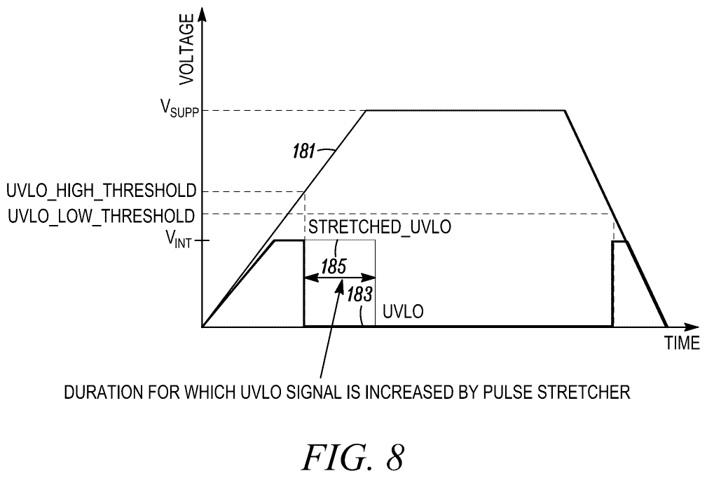

A function of the under voltage lock-out circuit 140 is to change a state of its output signals (UVLO 183, stretched_UVLO 185, stretched_UVLO_b 187 and UVLO_b 189) as V_{SUPP} crosses a specified threshold. The output signals from the under voltage lock-out circuit 140 are used to enable/disable various circuitry in the GaN driver 110. A value of V_{SUPP} 181 at which the under voltage lock-out circuit 140 changes the state of its output signals is a UVLO threshold. Normally, a UVLO threshold while V_{SUPP} 181 is ramping up is kept slightly higher than a UVLO threshold when V_{SUPP} is ramping down, and the two are known as a positive-going threshold (UVLO_high_threshold) and a negative-going threshold (UVLO_low_threshold), respectively. See FIG. 8. A difference between the two is UVLO hysteresis.

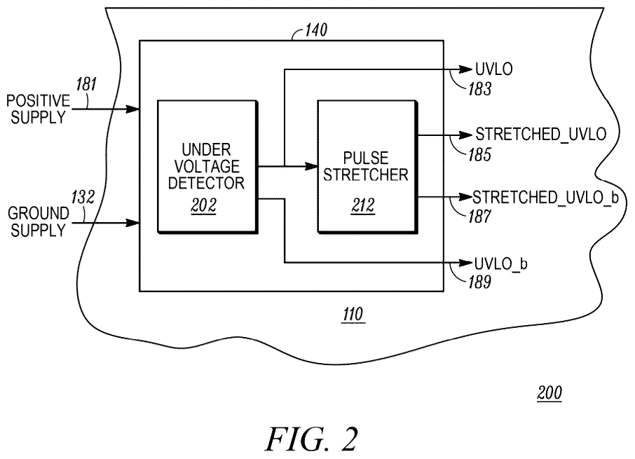

FIG. 2 is a simplified block diagram 200 of subsystem-level architecture of a first embodiment of the under voltage lock-out circuit 140 in accordance with the invention. The first embodiment of the under voltage lock-out circuit 140 comprises an under-voltage detector 202 in accordance with the invention, and a pulse stretcher 212 in accordance with the invention.

For the detection of an under-voltage condition of the supply voltage V_{SUPP} 181, the supply voltage V_{SUPP} is compared against a reference voltage. In the first embodiment of the under voltage lock-out circuit 140 the reference voltage is internally derived. The under-voltage detector 202 generates the UVLO signal 183 and the UVLO_b signal 189. The under-voltage detector 202 outputs the UVLO signal 183 to the pulse stretcher 212. The under-voltage detector 202 outputs the UVLO signal 183 and the UVLO_b signal 189 to the bias-less dynamic Miller clamp 160.

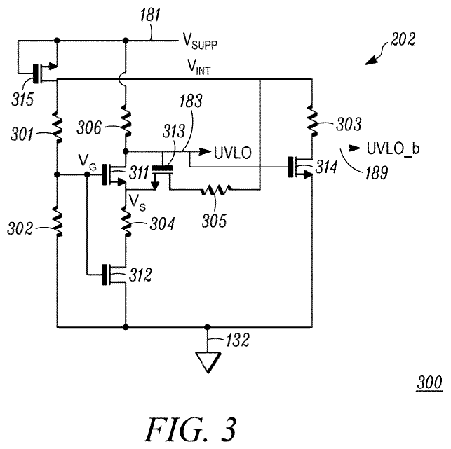

FIG. 3 is a simplified schematic 300 of the under-voltage detector 202. In this embodiment, the under-voltage detector 202 derives its reference voltage V_{INT} from the supply voltage V_{SUPP}. V_{INT} is a scaled version of the supply voltage V_{SUPP} which is the voltage being monitored by the under voltage lock-out circuit 140. The simplified schematic 300 includes a GaN transistor 315 whose source terminal and gate terminal are coupled to the positive supply terminal, and whose drain terminal is coupled to one end of a resister divider comprising GaN resistor 301 and GaN resistor 302. Another end of the resistor divider is coupled to the ground terminal 132. The supply voltage V_{SUPP} 181 passes through GaN transistor 315 and generates a voltage V_{INT} at its drain terminal. V_{INT} is scaled down by the resistor divider. The voltage V_{INT} is a diode drop lower than the supply voltage V_{SUPP} 181. A node between GaN resistor 301 and GaN resistor 302 is coupled to a gate terminal of GaN transistor 311 and to a gate terminal of GaN transistor 312. A GaN resistor 304 is coupled between a source terminal of GaN transistor 311 and a drain terminal of GaN transistor 312.

The simplified schematic 300 also includes a GaN resistor 306 having one end coupled to the positive supply terminal and having another end coupled to a drain terminal of GaN transistor 311 and to a gate terminal of GaN transistor 313. A source terminal of GaN transistor 313 is coupled to the source terminal of GaN transistor 311. GaN resistor 305 is coupled between the drain terminal of GaN transistor 313 and a drain terminal of GaN transistor 315. The simplified schematic 300 also includes a GaN transistor 314 having a source terminal coupled to the ground terminal 132 and a gate terminal coupled to the drain terminal of GaN resistor 311.

The simplified schematic 300 includes a GaN transistor 314 having a gate terminal coupled to the drain terminal of GaN transistor 311, a source terminal coupled to the ground terminal 132, and a drain terminal coupled to one end of a GaN resistor 303. The other end of GaN resistor 303 is coupled to the internal reference voltage V_{I}NT at the drain terminal of GaN transistor 315. A voltage at the drain terminal of GaN transistor 311 produces the UVLO signal 183. A voltage at the drain of GaN transistor 314 produces the UVLO_b signal 189.

As the voltage V_{SUPP} rises, the UVLO signal 183 tracks the supply voltage V_{SUPP} 181.

Once V_{INT} reaches a voltage greater than the threshold voltage of GaN transistor 311 and the voltage drop across resistor 304, transistor 311 turns on, the voltage of the UVLO signal 183 goes to zero and the voltage of the UVLO_b signal 189 goes to V_{INT}.

Likewise, as V_{SUPP} starts to fall and drops below the required gate-to-source voltage of GaN transistor 311, GaN transistor 311 turns off, and the UVLO signal 183 starts to track the positive supply V_{SUPP}.

Advantageously, the simplified schematic 300 generates the UVLO signal 183 without relying on a bandgap voltage, without using an external reference voltage and without using a traditional voltage comparator.

Advantageously, the positive-going threshold (UVLO_high_threshold) of the simplified schematic 300 is greater than 2V_{T} of the fabrication process. Furthermore, the positive-going threshold tracks the V_{T} of the fabrication process.

The low-to-high voltage threshold (UVLO_high_threshold) occurs when the GaN transistor 311 and GaN transistor 312 turn on as V_{SUPP} ramps from 0V to final value.

GaN transistor 311 and GaN transistor 312 turn on as V_{G} reaches one V_{T} above V_{S}.

V_{G} is V_{SUPP}−V_{T}−V₃₀₁.

Therefore, the low-to-high threshold (referenced to V_{SUPP}) voltage is:

V_{S}+V_{T}+V₃₀₁+V_{T315}→V_{S}+2V_{T}+V₃₀₁.

A minimum low-to-high threshold voltage is 2V_{T}+V_{HYS}+V₃₀₁, where V_{HYS} is hysteresis voltage. In the simplified circuit 300, V_{HYS}=V_{S}.

When GaN transistor 311 and GaN transistor 312 turn on, i.e., when they cross the low-to-high voltage threshold (UVLO_high_threshold), current through GaN transistor 311 is advantageously designed to be very small; thus, voltage at node V_{S} and the UVLO signal 183 is near zero. When GaN transistor 311 and GaN transistor 312 are off, GaN transistor 313 is on. The simplified schematic 300 is designed such that current through GaN transistor 313 is high enough to generate the V_{S} voltage which is the hysteresis voltage. Therefore, a high-to-low threshold voltage (UVLO_low_threshold) is 2V_{T}+V₃₀₁.

The minimum UVLO threshold tracks the process because the UVLO threshold is a function of V_{T} which changes with process.

The resistor 304 contributes to hysteresis generation for the under-voltage detector 202.

Advantageously, with the simplified schematic 300, the comparison of a reference voltage with V_{SUPP} is made without requiring complicated comparators. Advantageously, because of its inverter-based comparison, the simplified schematic 300 is much faster than any known comparator-based under voltage lock-out circuits. The inverter comprises GaN resistor 303 and GaN transistor 314.

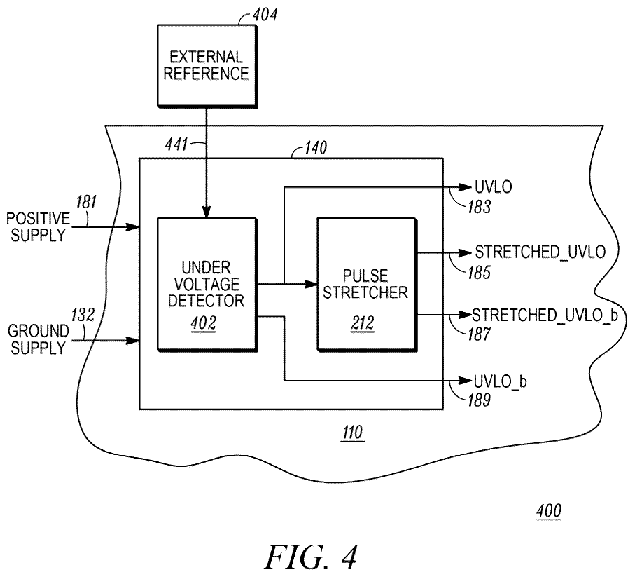

FIG. 4 is a simplified block diagram 400 of subsystem-level architecture of a second embodiment of the under voltage lock-out circuit 140 in accordance with the invention. The second embodiment of the under voltage lock-out circuit 140 comprises an under-voltage detector 402 and the pulse stretcher 212. The second embodiment of the under voltage lock-out circuit 140 is coupled to an external reference device 404.

More specifically, the external reference device 404 is located external to the die 130. In one embodiment, the external reference device 404 is located external to the microelectronic package in which the die 130 is disposed. The external reference device 404 can be any suitable device or integrated circuit used for dedicated reference generation. The external reference 404 can be a shunt regulator diode. The external reference 404 can be a low drop-out regulator. The external reference device 404 generates an external reference voltage 441.

For the detection of an under-voltage condition of the supply voltage V_{SUPP} 181, the supply voltage V_{SUPP} is compared against a reference voltage. In the second embodiment of the under voltage lock-out circuit 140 the external reference voltage 441 is used by the under voltage lock-out circuit to produce an internal reference voltage V_{INT}. For the detection of the under-voltage condition, the supply voltage V_{SUPP} 181 is compared against the internal reference voltage V_{INT}. With the second embodiment of the under voltage lock-out circuit 140, the external reference device 404 can be referred to either a low supply (ground) or a high supply (the voltage that is being monitored). In either case of referring, the second embodiment of the under voltage lock-out circuit 140 outputs signals (UVLO 183, stretched_UVLO 185, stretched_UVLO_b 187 and UVLO_b 189) in response to the value of V_{SUPP} 181.

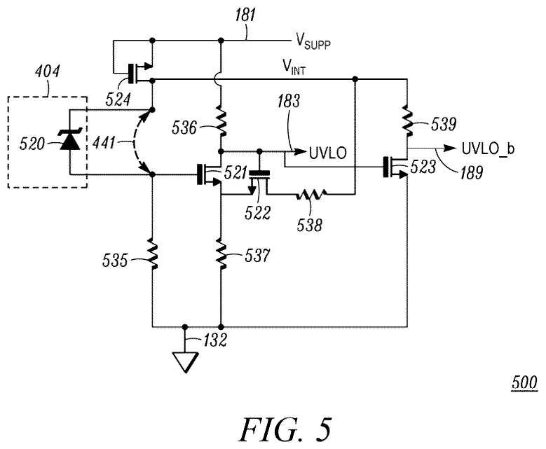

FIG. 5 is a simplified schematic 500 of one embodiment of the under-voltage detector 402. In the embodiment of the under-voltage detector 402 illustrated in FIG. 5 the external reference 404 is referred to the high side supply, i.e., the positive supply. In one embodiment of the under-voltage detector 402, the external reference 404 is Zener diode 520. The Zener diode 520 provides a bandgap-based reference voltage 441 and is fabricated using silicon process. The external reference voltage 441 shown in FIG. 4 is a voltage across the Zener diode 520.

The simplified schematic 500 includes a GaN transistor 524 having a gate terminal and a source terminal coupled to the supply voltage V_{SUPP} 181 and a drain terminal coupled to a cathode of the Zener diode 520. The anode of the Zener diode 520 is coupled to one end of a GaN resistor 535. The other end of GaN resistor 535 is coupled to the ground terminal 132. The supply voltage V_{SUPP} 181 passes through GaN transistor 524 and generates an internal reference voltage V_{INT} which goes to the Zener diode 520 biased by GaN resistor 535.

The simplified schematic 500 also includes a GaN resistor 536 having one end coupled to the positive supply terminal and the other end coupled to a drain terminal of a GaN transistor 521. A gate terminal of GaN transistor 521 is coupled to a node between Zener diode 520 and GaN resistor 535. A source terminal of GaN transistor 521 is coupled to one end of a GaN resistor 537. The other end of GaN resistor 537 is coupled to the ground terminal 132. A voltage at the drain of GaN transistor 521 produces the UVLO signal 183. As the voltage V_{SUPP} rises the voltage of the UVLO signal 183 tracks the positive supply V_{SUPP}.

The simplified schematic 500 further includes a GaN transistor 522 having a gate terminal coupled to the drain terminal of GaN transistor 521, a source terminal coupled to the source terminal of GaN transistor 521 and a drain terminal coupled to one end of a GaN resistor 538. The other end of GaN resistor 538 is coupled to the internal reference voltage V_{INT} at the drain terminal of GaN resistor 524.

The simplified schematic 500 includes a GaN transistor 523 having a gate terminal coupled to the drain terminal of GaN transistor 521, a source terminal coupled to the ground terminal 132, and a drain terminal coupled to one end of a GaN resistor 539. The other end of GaN resistor 539 is coupled to the internal reference voltage V_{INT} at the drain terminal of GaN transistor 524. A voltage at the drain of GaN transistor 523 produces the UVLO_b signal 189.

The internal voltage V_{INT} is a diode drop lower than the supply voltage V_{SUPP} 181. Once V_{INT} reaches a voltage greater than the breakdown voltage V_{Z} of the Zener diode, the threshold voltage of GaN transistor 521 and the voltage drop across resistor 537, GaN transistor 521 turns on, the output voltage UVLO falls to zero and the other output voltage UVLO_b goes to V_{INT}. Likewise, as V_{SUPP} starts to fall and crosses the threshold voltage of GaN transistor 521 it turns off, and the output voltage UVLO starts to track V_{SUPP}.

The resistor 537 contributes to the hysteresis generation for the output voltage UVLO, as follows. A voltage drop across resistor 537 is equal to the current flowing through resistor 538 and GaN transistor 522 times the value of resistor 537. Likewise, the voltage drops across 537 is equal to the current flowing through GaN resistor 536 and GaN transistor 521 times the value of resistor 537. By design, GaN resistor 536 is larger than GaN resistor 538, so in two voltage conditions it gives two different voltages across the resistor 537 which in turn generates the hysteresis voltage.

Advantageously, the simplified schematic 500 generates the UVLO signal 183 largely independent of process variation and largely independent of V_{T}.

The simplified schematic 500 is a complete GaN-based monolithically integrated under voltage lock-out circuit that can use any reference device. Because the simplified schematic 500 is an inverter-based design, it has an ultra-fast response time in the order of 50 ns at the expense of a few microamperes of current. The inverter comprises GaN resistor 539 and GaN transistor 523.

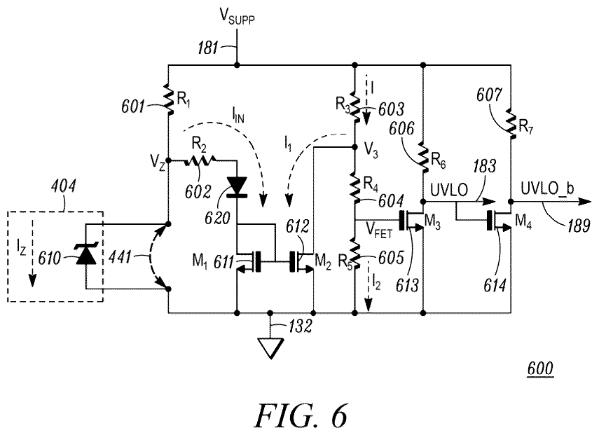

FIG. 6 is a simplified schematic 600 of another embodiment of the under-voltage detector 402. In the embodiment of the under-voltage detector 402 shown in FIG. 6, the external reference 404 is referred the low side supply, i.e., the ground terminal 132. In this embodiment of the under-voltage detector 402, the external reference 404 is a Zener diode 610. The Zener diode D_{Z} 610 provides a bandgap-based reference voltage 441 and is fabricated using silicon process.

The simplified schematic 600 of the under-voltage detector 402 includes a GaN resistor R₁ 601 coupled between a positive supply terminal V_{SUPP} and a cathode of Zener diode 610. An anode of Zener diode 610 is coupled to the ground terminal 132. A current through Zener diode 610 is I_{Z}. The external reference voltage 441 shown in FIG. 4 is a voltage across Zener diode 610. A GaN resistor R₂ 602 is coupled between the cathode of Zener diode 610 and an anode of GaN diode 620. A cathode of GaN diode 620 is coupled to a drain terminal of GaN transistor M₁ 611.

The simplified schematic 600 of the under-voltage detector 402 further comprises a GaN resistor R₃ 603 with one end coupled to the positive supply terminal V_{SUPP} and another end coupled to one end of a GaN resistor R₄ 604. The other end of GaN resistor R₄ 604 coupled to one end of GaN resistor Rₛ 605. The other end of GaN resistor Rₛ 605 is coupled to the ground terminal 132.

The simplified schematic 600 of the under-voltage detector 402 comprises a resistor R₆ 606 having one end coupled to the positive supply terminal V_{SUPP} and another end coupled to a drain terminal of GaN transistor M₃ 613. A gate terminal of GaN transistor M₃ 613 is coupled to a node between GaN resistor R₄ 604 and GaN resistor Rₛ 605. A source terminal of GaN transistor M₃ 613 is coupled to the ground terminal 132.

The simplified schematic 600 of the under-voltage detector 402 compares a reference voltage with the positive supply V_{SUPP}. The simplified schematic 600 minimizes the effects of process variations on the threshold voltage V_{T} of GaN transistor M₃ 613. In doing so, a current proportional to V_{T} of GaN transistor 613 is subtracted, using a current mirror, from a resistance network comprising GaN resistor 603, GaN resistor 604 and GaN resistor 605. As the V_{SUPP} builds up, the voltage V_{FET} at the gate of the GaN transistor 613 reaches V_{T} and it turns on. A voltage at a drain of GaN transistor 613 produces the output signal UVLO 183.

The simplified schematic 600 also includes a GaN resistor R₇ 607 having one end coupled to the positive supply terminal V_{SUPP} and another end coupled to a drain terminal of GaN transistor M₄ 614. A gate terminal of GaN transistor M₄ 614 is coupled to the drain terminal of GaN transistor M₃ 613. A source terminal of GaN transistor M₄ 614 is coupled to the ground terminal. A voltage at a drain of GaN transistor M₄ 614 produces the output signal UVLO_b 189.

The Zener diode D_{Z} 610 generates a voltage V_{Z}. The Zener diode D_{Z} 610 is biased by resistor R₁ 601.

The current I_{EV} through GaN transistor M₁ 611 is equal to (V_{Z}−2V_{T})/R₁.

A current mirror comprising GaN transistor M₁ 611 and GaN transistor M₂ 612 copies the current I_{IN} through GaN transistor M₂ 612. The current through GaN transistor M₂ 612 is equal to I₁=I_{IN}.

A current through GaN resistor R₃ 603 is equal to I₁+I₂. I₂ is equal to the voltage drop V_{FET}/R₅. The voltage V₃ is the sum of the voltage drop across resistors R₄ and R₅, which is equal to V_{FET}+V_{FET}(R₄/R₅).

Therefore, the voltage being monitored, V_{SUPP}, which appears across the resistor divider consisting of R₃, R₄ and R₅, is V_{FET}(1+R₄/R₅)+IR₃ which is equivalent to V_{FET}(1+R₄/R₅)+{(V_{Z}−2V_{T})/R₁+V_{FET}/R₅}R₃. The voltage V_{FET}, which turns on GaN transistor M₃ 613 and decides the threshold of the UVLO, is

$${V}_{FET} = {kV}_{SUPP} + ( 2 {R}_{3} {R}_{5} ) / {R}_{2} ( {R}_{3} + {R}_{4} + {R}_{5} ) * {V}_{T} - ( {R}_{3} {R}_{5} ) / {R}_{2} ( {R}_{3} + {R}_{4} + {R}_{5} ) * {V}_{Z} .$$

The value of k=R₅/(R₃+R₄+R₅) can be chosen as a design parameter to make the quotient of the second term equal to one. The quotient of the third term can be chosen by considering V_{FET} (which is the turn-on voltage) equal to the threshold voltage. As a result, a UVLO threshold that does not have any V_{T}-dependent parameter is obtained. Consequently, the embodiment of the under-voltage detector 402 illustrated in FIG. 6 has process compensation.

A quantitative analysis of the circuit shown in FIG. 6 is given below.

The current flowing through M₁ is I_{IN}=(V_{Z}−2V_{T})/R₂.

Similarly, current I through R₃ is I₁+I₂, where I₂=V_{FET}/R₅.

$${V}_{3} = {V}_{FET} + {V}_{FET} ( {R}_{4} / {R}_{5} )$$

$${V}_{3} = {V}_{FET} ( 1 + {R}_{4} / {R}_{5} )$$

$${V}_{SUPP} = {V}_{FET} ( 1 + {R}_{4} / {R}_{5} ) + ( {I}_{1} + {I}_{2} ) {R}_{3}$$

$${V}_{SUPP} = {V}_{FET} ( 1 + {R}_{4} / {R}_{5} ) + \{ ( {V}_{Z} - 2 {V}_{T} ) / {R}_{2} \} {R}_{3} + ( {V}_{FET} / {R}_{5} ) {R}_{3}$$

Current I₁ and I_{IN} are same because of current mirroring.

$${V}_{FET} = \{ {R}_{5} / ( {R}_{3} + {R}_{4} + {R}_{5} ) \} {V}_{SUPP} + ( 2 {V}_{T} - {V}_{Z} ) ( {R}_{3} / {R}_{2} ) \{ {R}_{5} / ( {R}_{3} + {R}_{4} + {R}_{5} ) \}$$

$${V}_{FET} = {kV}_{SUPP} + ( 2 {R}_{3} {R}_{5} ) / {R}_{2} ( {R}_{3} + {R}_{4} + {R}_{5} ) * {V}_{T} - ( {R}_{3} {R}_{5} ) / {R}_{2} ( {R}_{3} + {R}_{4} + {R}_{5} ) * {V}_{Z}$$

The value of k is chosen as per design, and the choice of the value of k makes the quotient of the second term equal to one. The quotient of the third term is chosen by considering the V_{FET} voltage equal to the threshold voltage. In this way, the resistance values are chosen.

All known Zener-based under voltage lock-out circuits use a Zener diode in the high side. Advantageously, the simplified schematic 600 uses a reference voltage in the low side; consequently, it is easier to integrate the simplified schematic 600 with a Zener-based linear regulator because all known Zener-based linear regulators use a reference voltage with respect to the low side. Advantageously, with an appropriate choice of the design parameter, the simplified schematic 600 has an UVLO threshold that does not depend on the V_{T} of GaN devices.

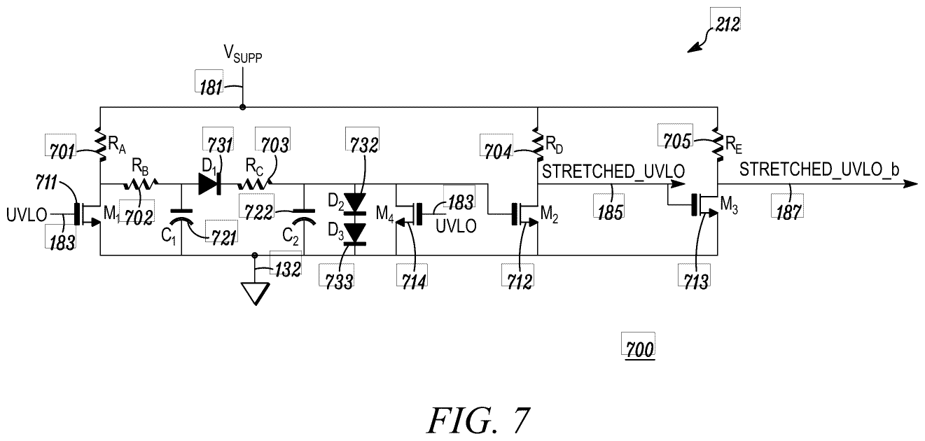

FIG. 7 is a simplified schematic 700 of an embodiment of the pulse stretcher 212. Because of an absence of a bandgap voltage in the under-voltage detectors shown in FIGS. 3, 5 and 6, the under-voltage detectors in accordance with the invention cannot accurately measure the supply voltage V_{SUPP} 181; therefore, the pulse stretcher 212 is useful. The under voltage lock-out circuit 140 continually generates the UVLO signal 183 but only as long as a low-voltage condition exists with respect to V_{SUPP}. The pulse stretcher 212 is synchronous to the under-voltage detector 202 and 402. A width of the stretched_UVLO 185 depends on how soon the UVLO signal 183 goes low. Therefore, the UVLO signal 183 coordinates the pulse stretcher 212. The pulse stretcher 212 increases a duration, i.e., width, of the UVLO signal 183 by a fixed amount. In one embodiment of the pulse stretcher 212, when the supply voltage V_{SUPP} 181 has a ramp rate of 50 ns, the width of the stretched_UVLO 185 ramp is 60 ns. As the ramp rate of the supply voltage V_{SUPP} 181 changes, so does the width of the stretched_UVLO 185.

The pulse stretcher 212 includes a GaN resistor R_{A} 701 coupled between a positive supply terminal V_{SUPP} and a drain terminal of a GaN transistor M₁ 711. A source terminal of GaN transistor M₁ 711 is coupled to the ground terminal 132. A gate terminal of GaN transistor M₁ 711 is coupled to the UVLO signal 183 outputted by the under-voltage detector 140. One end of a GaN resistor R_{B} 702 is coupled to the drain terminal of GaN transistor 711 and another end of the GaN resistor R_{B} is coupled to a GaN capacitor Ci 721 and to an anode of a GaN diode Di 731. Another end of GaN capacitor Ci 721 is coupled to the ground terminal 132.

A cathode of GaN diode D₁ 731 is coupled to one end of GaN resistor R_{C} 703. Another end of GaN resistor R_{C} 703 is coupled to one end of GaN capacitor C₂ 722, to an anode of GaN diode D₂ 732, to a drain terminal of GaN transistor M₄ 714 and to a gate terminal of GaN transistor M₂ 712. A cathode of GaN diode D₂ 732 is coupled to an anode of GaN diode D₃ 733. A cathode of GaN diode D₃ 733 is coupled to the ground terminal 132. A source terminal of GaN transistor M₄ 714 is coupled to the ground terminal 132. A gate terminal of GaN transistor M₄ 714 is coupled to the UVLO output signal 183 outputted by the under-voltage detector 140.

A GaN resistor R_{D} 704 is coupled between the positive supply terminal and a drain terminal of GaN transistor M₂ 712. The pulse stretcher 212 produces the stretched_UVLO signal 185 at the drain terminal of GaN transistor M₂ 712. A source terminal of GaN transistor M₂ 712 is coupled to the ground terminal 132.

A GaN resistor R_{E} 705 is coupled between the positive supply terminal and a drain terminal of GaN transistor M₃ 713. A gate terminal of GaN transistor M₃ 713 is coupled to the drain terminal of GaN transistor M₂ 702. A source terminal of GaN transistor M₃ 713 is coupled to the ground terminal 132. The pulse stretcher 212 produces the stretched_UVLO_b signal 187 at the drain of drain terminal of GaN transistor M₃ 713.

As the supply voltage V_{SUPP} 181 rises from zero, the input signal (UVLO 183) to the pulse stretcher 212 is also rising from zero. If UVLO 183 is below the threshold voltage, GaN transistors M₁ 711 and M₂ 712 remain in cutoff and the output signal (stretched_UVLO 185) from the pulse stretcher 212 follows the supply voltage V_{SUPP} 181 with a delay given by Equation (1) below. During this interval, GaN capacitor C₁ 721 is charged to a certain voltage.

With a slower ramp rate of the supply voltage V_{SUPP} 181, it takes more time for V_{SUPP} to reach a final steady state value. With a faster ramp rate of the supply voltage V_{SUPP} 181, it takes less time for V_{SUPP} to reach a final steady state value. Therefore, the pulse stretcher 212 advantageously extends the UVLO signal 183 by a predetermined amount of time depending on a ramp rate of V_{SUPP} and an amplitude of V_{SUPP}. The predetermined amount of time is a function of ramp rate of the supply voltage. The predetermined amount of time increases as the ramp rate of the supply voltage decreases.

When UVLO 183 crosses the threshold voltage, GaN transistor M₁ 711 turns on, GaN capacitor C₁ 721 discharges through R_{B} 702 and stretched_UVLO 185 starts to rise and follows V_{SUPP} with a R_{C} delay given by Equation (1).

$${τ}_{output} = {R}_{D} ( {C}_{DS 2} + {C}_{DB 2} + {C}_{GS 3} ) \qquad ( 1 )$$

where C_{DS2} is capacitance between the drain and the source of GaN transistor M₂ 712, where C_{DB2} is capacitance between the drain and the base of GaN transistor M₂ 712, and where C_{GS3} is capacitance between the gate and the source of GaN transistor M₃ 713.

A delay between the UVLO 183 and stretched_UVLO 185 occurs due to a delay within pulse stretcher 212.

Once a rising supply voltage V_{SUPP} 181 has crossed the UVLO_high_threshold (see FIG. 8), the input signal (UVLO 183) to the pulse stretcher 212 drops to zero; therefore, the transistor M₁ turns off and GaN capacitor Ci 721 starts to charge through GaN resistor R_{A} 701 and GaN resistor R_{B} 702 with a time constant given by Equation (2). As the supply voltage V_{SUPP} 181 grows across GaN capacitor Ci and crosses the threshold voltage of diode D₁ 731, diode D₁ starts to conduct and the GaN capacitor C₂ 722 starts to charge with a R_{C} delay given by Equation (3).

$${τ}_{1} = ( {R}_{a} + {R}_{b} ) {C}_{1} \qquad ( 2 )$$

$${τ}_{2} = {R}_{c} ( {C}_{2} + {C}_{GS 3} ) \qquad ( 3 )$$

where C_{GS3} is a gate-to-source capacitance of GaN transistor M₃ 713.

Slowly, the voltage at a gate of GaN transistor M₂ 712 crosses its threshold voltage and it turns on while pulling down stretched_UVLO 185 to zero. Then, stretched_UVLO_b 187 goes high. Therefore, as V_{SUPP} starts to rise, a signal at the output of the pulse stretcher is delayed from the input signal by τ₁+τ₂. Similarly, as V_{SUPP} starts to fall, a signal at the output of the pulse stretcher 212 is delayed from the signal at the input of the pulse stretcher by τ₁+τ₂.

Advantageously, the under voltage lock-out circuit 140 is capable of working with an ultra-fast ramp rate of V_{SUPP}. Laboratory results have shown that the under voltage lock-out circuit 140 is responsive for a ramp rate of the voltage supply in the order of 40-50 ns.

The pulse stretcher 212 can be added to any of the illustrated embodiments (simplified schematic 300, 500 and 600) of the under-voltage detector 140.

Advantageously, the pulse stretcher 212 is an all-GaN-based approach that enhances a fault signal, i.e., UVLO signal 183 by a definite length of time.

FIG. 8 shows that the UVLO signal 183 goes from high to low once the voltage being monitored, V_{SUPP}, crosses a UVLO_high_threshold voltage. However, FIG. 8 shows that V_{SUPP} is still ramping up beyond the UVLO_high_threshold voltage. For a high ramp rate of V_{SUPP}, internal circuitry of the driver 110 may not have settled to a steady state and the driver could unintentionally turn on the GaN power switch 120. A function of the pulse stretcher 212 is to keep a gate of the GaN power switch 120 low until V_{SUPP} is settled to a final value. This is done by generating stretched_UVLO 185 which is triggered for a predetermined duration after the UVLO signal 183 has triggered. The predetermined duration typically continues until after V_{SUPP} is settled. The stretched_UVLO signal 185 is basically a delayed version of the UVLO signal 183.

The pulse stretcher 212 minimizes an effect of process-related threshold variation of the under voltage lock-out circuit 140 without using any complicated GaN-based comparator architecture.

Other embodiments (not shown) of the pulse stretcher 212 can comprise a monostable multi-shot generator or a one-shot generator.

The output signals of the under voltage lock-out circuit 140 go to various other circuits and devices, wherein the final output signals turn on/off the other circuits and devices, and/or enable/disable the other circuits and devices. Appropriate level shifts or other signal conditioning may be added to make the output signals of the under voltage lock-out circuit 140 more useful.

In each embodiment under voltage lock-out circuit in accordance with the invention, the comparison of the reference voltage with the supply voltage V_{SUPP} 181 is made without requiring complicated comparators.

All known under voltage lock-out circuits use an external voltage reference that can only be referred to a ground terminal or to a low-side-supply rail. Advantageously, with the under voltage lock-out circuit 140 in accordance with the invention, the Zener diode 520 and 610 or any other external reference voltage can be, and is, referred to the positive supply voltage or high-side-supply rail.

Except for the external reference 404, all the devices of the circuits in accordance with the invention are realized through only N-channel enhancement-mode GaN HEMTs and by diodes and resistors and capacitors that are fabricated in GaN processes. No P-type metal oxide semiconductor device is used in the circuits in accordance with the invention, except that the external reference 404 may comprise one or more P-type metal oxide semiconductor devices.

The circuits in accordance with the invention, except for the external reference 404, are capable of being on a same GaN die 104. The GaN driver 110 and the GaN power switch 120 being on one GaN die 104 provides excellent response compared to being on more than one GaN die. A single die also provides reduction of cost and complexity compared to more than one die.

In another embodiment (not shown), the GaN driver 110 and the GaN power switch 120 are on separate dies, but the separate dies are in a same microelectronic package. In yet another embodiment (not shown), the GaN driver 110 and the GaN power switch 120 are in separate microelectronic packages.

Although most of the description herein focuses on GaN HEMT based technology, the topology of the disclosed circuits and their application are independent of the device technology platform, and can be easily extended to silicon or other present or future semiconductor platforms.

Some features of the present invention may be used in an embodiment thereof without use of other features of the present invention. As such, the foregoing description should be considered as merely illustrative of the principles, teachings, examples, and exemplary embodiments of the present invention, and not a limitation thereof.

These embodiments are only examples of the many advantageous uses of the innovative teachings herein. In general, statements made in the specification of the present application do not necessarily limit any of the various claimed inventions. Moreover, some statements may apply to some inventive features but not to others.

The circuit as described above is part of the design for an integrated circuit chip. A design of the chip is created in a graphical computer programming language, and stored in a computer storage medium (such as a disk, tape, physical hard drive, or virtual hard drive such as in a storage access network). If a designer does not fabricate chips or photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into an appropriate format (e.g., GDSII) for fabrication of photolithographic masks, which typically include multiple copies of the chip design that are to be formed on a wafer. The photolithographic masks are utilized to define areas of the wafer (and/or the layers thereon) to be etched or otherwise processed.

The methods as discussed above are used in fabrication of integrated circuit chips. The resulting integrated circuit chips can be distributed by a fabricator in raw wafer form (that is, as a single wafer that has multiple unpackaged chips), as a bare chip, or in a packaged form. In the latter case, the chip is mounted in a single chip package or in a multichip package. In any case, the chip is then integrated with other chips, discrete circuit elements, and/or other signal processing devices as part of either (a) an intermediate product, such as a motherboard, or (b) an end product. An end product can be any product that includes integrated circuit chips, ranging from toys and other low-end applications to advanced computer products (such as, but not limited to, an information processing system) having a display, a keyboard, or other input device, and a central processor.

Unless stated otherwise, terms such as “first” and “second” are used to arbitrarily distinguish between the elements that such terms describe. Thus, these terms are not necessarily intended to indicate temporal or other prioritization of such elements.

The terms “a” or “an”, as used herein, are defined as one as or more than one. The term plurality, as used herein, is defined as two as or more than two. Plural and singular terms are the same unless expressly stated otherwise. The term another, as used herein, is defined as at least a second or more. The terms including and/or having, as used herein, are defined as comprising (i.e., open language). The term coupled, as used herein, is defined as connected, although not necessarily directly, and not necessarily mechanically. The terms program, software application, and the like as used herein, are defined as a sequence of instructions designed for execution on a computer system. A program, computer program, or software application may include a subroutine, a function, a procedure, an object method, an object implementation, an executable application, an applet, a servlet, a source code, an object code, a shared library/dynamic load library and/or other sequence of instructions designed for execution on a computer system.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. An under voltage lock-out circuit, comprising:
a supply voltage input;
an under voltage lock-out signal output;
a reference voltage circuit interface;
a first GaN transistor having:
a first source and a first gate both coupled to the supply voltage input; and
a drain first coupled to a first port of the reference voltage circuit interface;
a second GaN transistor having:
a second gate coupled to the first drain via a second port of the reference voltage circuit interface;
a second drain coupled to the under voltage lock-out signal output and coupled, via a first resistor, to the supply voltage input; and
a second source coupled, via a second resistor, to a ground potential;
a third GaN transistor having:
a third gate coupled to the under voltage lock-out signal output;
a third drain coupled through a third resistor to the first source; and
a third source coupled to the second drain.

2. The under voltage lock-out circuit of claim 1, wherein a value of the first resistor and a value of the third resistor are chosen to provide a hysteresis value defining a difference between a low-to-high threshold value and a high-to-low threshold value of voltages present on the supply voltage input that cause a change of state of the under voltage lock-out signal output.

3. The under voltage lock-out circuit of claim 1, wherein the first GaN transistor, the second GaN transistor, and the third GaN transistor are formed on a single substrate.

4. The under voltage lock-out circuit of claim 1, further comprising a voltage reference that comprises a resister divider coupled to the first port and the second port, wherein the first port is coupled to an input of the resister divider and the second port is coupled to a node between resisters of the resister divider.

5. The under voltage lock-out circuit of claim 1, further comprising a voltage reference coupled to the reference voltage circuit interface, the voltage reference comprising an external bandgap voltage reference, wherein the first port is coupled to a first connection of the external bandgap voltage reference and the second port is coupled to a second connection of the external bandgap voltage reference.

6. The under voltage lock-out circuit of claim 1, further comprising a pulse stretcher comprising an input terminal coupled to the under voltage lock-out signal output, the pulse stretcher operating to produce a stretched under voltage lock-out output based on receipt of an indication on the under voltage lock-out signal output.

7. The under voltage lock-out circuit of claim 6, wherein the pulse stretcher comprises:
a first stretcher transistor having a drain, a source coupled to ground potential, and a gate coupled to the input terminal of the pulse stretcher,
a first stretcher resistor coupled between the supply voltage input and the drain of the first stretcher transistor,
a second stretcher resistor having one end coupled to the drain of the first stretcher transistor,
a first capacitor coupled between another end of the second stretcher resistor and ground potential,
a first diode having an anode coupled to the other end of the second stretcher resistor,
a third stretcher resistor having one end coupled to a cathode of the first diode,
a second capacitor coupled between another end of the third stretcher resistor and ground potential,
a second diode having an anode coupled to another end of the third stretcher resistor,
a third diode having an anode coupled to ground potential,
a second stretcher transistor having a drain coupled to the other end of the third stretcher resistor, a source coupled to ground potential, and a gate coupled to the input terminal of the pulse stretcher,
a third stretcher transistor having a drain, a gate coupled to the other end of the third stretcher resistor, and a source coupled to ground potential, and
a fourth resistor coupled between the supply voltage and the drain of the third stretcher transistor,
wherein the stretched under voltage lock-out signal is produced at the drain of the third stretcher transistor.

8. An electronic circuit comprising:
a GaN FET power switch; and
a driver for the GaN FET power switch, the driver comprising:
a reference device for generating a reference voltage,
a GaN-based under-voltage detector comprising:
an under voltage lock-out signal output coupled one of directly or indirectly to the GaN FET power switch;
a first GaN transistor having:
a first source and a first gate both coupled to a supply voltage input; and
a first drain coupled to a first port of the reference device;
a second GaN transistor having:
a second gate coupled to the first drain via a second port of the reference device;
a second drain coupled to the under voltage lock-out signal output and coupled, via a first resistor, to the supply voltage input; and
a second source coupled, via a second resistor, to a ground potential;
a third GaN transistor having:
a third gate coupled to the under voltage lock-out signal output;
a third drain coupled through a third resistor to the first source; and
a third source coupled to the second drain.

9. The electronic circuit of claim 8, wherein a value of the first resistor and a value of the second resistor are chosen to provide a hysteresis value defining a difference between a positive-going threshold and a negative going threshold of voltages present on the supply voltage input that cause a change of state of the under voltage lock-out signal output.

10. The electronic circuit of claim 8, wherein the first GaN transistor, the second GaN transistor, and the third GaN transistor are formed on a single substrate.

11. The electronic circuit of claim 8, wherein the reference device comprises a resister divider, wherein the first port comprises an input to the resister divider and the second port comprises a connection to a node between two resisters of the resister divider.

12. The electronic circuit of claim 8, wherein the reference device comprises an external bandgap voltage reference, and the first port comprises a first connection of the external bandgap voltage reference and the second port comprises an electrical coupling between a second connection of the bandgap voltage reference and a third resistor connecting the second connection to the ground potential.

13. The electronic circuit of claim 8, further comprising a pulse stretcher comprising an input terminal coupled to the under voltage lock-out signal output, the pulse stretcher operating to produce a stretched under voltage lock-out based on receipt of an under-voltage indication.

14. The electronic circuit of claim 13, wherein the pulse stretcher comprises:
a first stretcher transistor having a drain, a source coupled to ground potential, and a gate coupled to the input terminal of the pulse stretcher,
a first stretcher resistor coupled between the supply voltage input and the drain of the first stretcher transistor,
a second stretcher resistor having one end coupled to the drain of the first stretcher transistor,
a first capacitor coupled between another end of the second stretcher resistor and ground potential,
a first diode having an anode coupled to the other end of the second stretcher resistor,
a third stretcher resistor having one end coupled to a cathode of the first diode,
a second capacitor coupled between another end of the third stretcher resistor and ground potential,
a second diode having an anode coupled to another end of the third stretcher resistor, a third diode having an anode coupled to ground potential,
a second stretcher transistor having a drain coupled to the other end of the third stretcher resistor, a source coupled to ground potential, and a gate coupled to the input terminal of the pulse stretcher,
a third stretcher transistor having a drain, a gate coupled to the other end of the third stretcher resistor, and a source coupled to ground potential, and
a fourth resistor coupled between the supply voltage and the drain of the third stretcher transistor,
wherein the stretched under voltage lock-out signal is produced at the drain of the third stretcher transistor.

15. An integrated circuit, comprising:
a substrate;
a GaN FET power switch disposed on the substrate; and
a GaN-based driver disposed on the substrate and coupled to the GaN FET power switch, the GaN-based driver having an input terminal for receiving a supply voltage, the GaN-based driver comprising:
a reference voltage circuit interface;
an under voltage lock-out signal output that is coupled one of directly or indirectly to the GaN FET power switch;
a GaN-based under-voltage detector comprising:
a first GaN transistor having:
a first source and a first gate both coupled to the input terminal; and
a first drain coupled to a first port of the reference voltage circuit interface;
a second GaN transistor having:
a second gate coupled to the first drain via a second port of the reference voltage circuit interface;
a second drain coupled to the under voltage lock-out signal output and coupled, via a first resistor, to the input terminal; and
a second source coupled, via a second resistor, to a ground potential;
a third GaN transistor having:
a third gate coupled to an under voltage lock-out signal output;
a third drain coupled through a third resistor to the first source; and
a third source coupled to the second drain,
wherein the GaN-based under-voltage detector outputs the under voltage lock-out signal when the supply voltage is below a low-to-high threshold value, and does not output the under voltage lock-out signal when the supply voltage is above the low-to-high threshold value.

16. The integrated circuit of claim 15, wherein the first GaN transistor, the second GaN transistor, and the third GaN transistor are each a respective N-channel enhancement-mode GaN high-electron-mobility transistor.

17. The integrated circuit of claim 15, wherein a minimum low-to-high threshold value is greater than 2 times a threshold voltage of fabrication process of the GaN-based driver.

18. The integrated circuit of claim 15, wherein the minimum low-to-high threshold tracks a threshold voltage of a fabrication process of the GaN-based driver.

19. The integrated circuit of claim 15, further comprising a pulse stretcher comprising an input terminal coupled to the under voltage lock-out signal output, the pulse stretcher operating to produce a stretched under voltage lock-out output for a predetermined amount of time based on receipt of an indication on the under voltage lock-out signal output, wherein the predetermined amount of time is a function of ramp rate of the supply voltage.

20. The integrated circuit of claim 19, wherein the predetermined amount of time increases as the ramp rate of the supply voltage decreases.
